(19) United States
(12) Patent Application Publication
(10) Pub. No.: US 2017/0101553 A1
(43) Pub. Date: Apr. 13, 2017

(54) PRESSURE SENSITIVE ADHESIVE SHEET, POLARIZING PLATE WITH PRESSURE SENSITIVE ADHESIVE, AND IMAGE DISPLAY DEVICE

(71) Applicant: NITTO DENKO CORPORATION, Osaka (JP)

(72) Inventors: Shou TAKARADA, Osaka (JP); Eiko SUEFUSA, Osaka (JP); Atsushi YASUI, Osaka (JP); Ryohei SAWAZAKI, Osaka (JP)

(73) Assignee: NITTO DENKO CORPORATION, Osaka (JP)

(21) Appl. No.: 15/287,921

(22) Filed: Oct. 7, 2016

(30) Foreign Application Priority Data
Oct. 13, 2015 (JP) 2015-202187

(51) Int. Cl. C09J 7/02; H01L 27/32; G02F 1/1335; C09J 133/06

(52) U.S. Cl. CPC C09J 7/0217; C09J 133/062; H01L 27/3232; C09J 7/0278; G02F 1/133528; C09J 2429/006; C09J 2433/00; C09J 2203/318; C09J 2205/114; G02F 2202/28

(57) ABSTRACT

The pressure sensitive adhesive sheet has a thickness of D, a water-vapor permeability of X, and a moisture content of Y. XD² is 2.7×10⁻⁶ g/24 h or more and Y/D is 47 m⁻¹ or less. A base polymer of a pressure sensitive adhesive composition that forms the pressure sensitive adhesive sheet is substantially free from an organic acid monomer component as monomer units. The pressure sensitive adhesive sheet is suitably used for bonding a polarizing plate to a transparent member disposed on a viewing-side of an image display device.

### TECHNICAL FIELD

The present invention relates to a pressure sensitive adhesive sheet, which is used for bonding a front transparent member and a polarizing plate in an image display device. The invention also relates to a polarizer with a pressure sensitive adhesive in which a polarizing plate and a pressure adhesive sensitive sheet are laminated, and an image display device in which a polarizing plate and a front transparent member are bonded with the pressure sensitive adhesive sheet interposed therebetween.

### BACKGROUND ART

Liquid crystal displays and organic EL displays are widely used as various kinds of image display devices of mobile phones, car navigation devices, personal computer monitors, televisions and so on. On a viewing-side outermost surface of an image display panel (a liquid crystal panel or an organic EL panel), a front transparent plate (also referred to as a “window layer” etc.) such as a transparent resin plate or a glass plate may be provided, for the purpose of, for example, preventing damage to the image display panel due to impact from the outer surface.

For arranging a front transparent plate on a front surface of an image display panel, an “interlayer filling structure” is proposed in which the front transparent plate and a polarizing plate disposed on the outermost surface of an image display panel are bonded with a pressure sensitive adhesive therebetween. In a case where a touch panel is arranged on a front surface of an image display panel, the interlayer filing structure is also employed in which interlayer space between the polarizing plate and the touch panel is filled with a pressure sensitive adhesive. In the interlayer filling structure, a gap between the panel and the front transparent member is filled with a pressure sensitive adhesive to decrease a refractive index difference at the interface, and therefore deterioration of visibility due to reflection and scattering is suppressed (see JP-A-2012-237965, for example). In recent years, interlayer filling structures using a pressure sensitive adhesive have been increasingly employed in the application of mobile displays of mobile phones, smartphones and the like which are mainly used outdoors.

Due to the increasing demand, application of the interlayer filling structure in on-vehicle displays such as car navigation devices is also considered. In general, on-vehicle displays are required to have durability at a higher temperature as compared to mobile displays.

### SUMMARY OF THE INVENTION

### Problems to be Solved by the Invention

JP-A-2014-102353 indicates that when an image display device in which a gap between an image display panel and a front transparent plate is filled with a pressure sensitive adhesive is subjected to a long-time high-temperature durability test required for on-vehicle displays, the transmittance at the in-plane central part of a polarizing plate that forms the image display panel decreases. The decrease in transmittance of the polarizing plate results from generation of polyene structure in polyvinyl alcohol, which forms a polarizer, under a high-temperature environment, and the decrease in transmittance tends to become more noticeable as the panel size increases. In order to suppress polyene structure generation in a polarizing plate that is disposed on a surface of an image display with an interlayer filling structure using a pressure sensitive adhesive, JP-A-2014-102353 proposes disposing a polarizing plate including a transparent protective film having a high water-vapor permeability on a surface of a polarizer.

In an image display device in which a gap between a polarizing plate and a front transparent member is filled with a pressure sensitive adhesive, a decrease in single transmittance of the polarizing plate due to polyene structure generation in polarizer tends to be suppressed by using a polarizing plate including a transparent protective film having a high water-vapor permeability. However, as a result of studies conducted by the inventors, it has been found that in a large screen size display device, the single transmittance of the polarizing plate tends to decrease in a high-temperature durability test even when a polarizer protective film having a high water-vapor permeability is used. It has also been found that when the ratio of decrease in single transmittance of the polarizing plate is low in the high-temperature durability test, the cross transmittance of the polarizing plate significantly increases, so that a black image display tends to look bluish.

An object of the present invention is to provide an image display device having an interlayer filling configuration and a polarizing plate interposed therein causes little optical characteristics change under a high-temperature environment.

### Means for Solving the Problems

It has been found from the further studies by the inventors that when a specific pressure sensitive adhesive sheet is used for bonding a polarizing plate to a front transparent member, deterioration of the characteristics of the polarizing plate under a high-temperature environment can be suppressed.

The present invention relates to a pressure sensitive adhesive sheet to be used for bonding a polarizing plate to a transparent member disposed on the viewing-side of an image display device. The pressure sensitive adhesive sheet satisfies the relations: XD² is 2.7×10⁻⁶ g/24 h or more; and Y/D is 47 m⁻¹ or less, where D is a thickness, X is a water-vapor permeability, and Y is a moisture content. The thickness D is preferably 50 μm to 500 μm.

An image display device in which a polarizing plate and a front transparent member are bonded together with the above pressure sensitive adhesive sheet of the present invention interposed therebetween is excellent in durability as a decrease in single transmittance and an increase in cross transmittance of the polarizing plate under a high-temperature environment hardly occur.

A pressure sensitive adhesive composition that forms the pressure sensitive adhesive sheet is preferably one including a base polymer whose monomer unit is substantially free from an organic acid monomer component. Preferably, the pressure sensitive adhesive composition contains 50% by weight or more of an acryl-based base polymer. Preferably, the acryl-based base polymer contains a hydroxy group-containing monomer and a nitrogen-containing monomer as monomer units. The total content of the hydroxy group-containing monomer and the nitrogen-containing monomer based on the total amount of constituent monomer components of the acryl-based base polymer is preferably 10 to 45% by weight.

Further, the present invention relates to a polarizing plate with a pressure sensitive adhesive layer including a polarizing plate having a polarizer formed of a polyvinyl alcohol-based film containing iodine and the pressure sensitive adhesive sheet disposed on first principal surface of the polarizing plate. In the polarizing plate, a transparent protective film provided on the first principal surface-side of the polarizer, which is a side the pressure sensitive adhesive sheet is disposed, preferably has a water-vapor permeability of 300 g/m²·24 h or more. The polarizing plate with a pressure sensitive adhesive layer according to the present invention may be a polarizing plate with a pressure sensitive adhesive layer on both sides which further includes a pressure sensitive adhesive sheet having a thickness of 35 μm or less on second principal surface of the polarizing plate.

### BRIEF DESCRIPTION OF THE DRAWINGS

FIG. 1 is a schematic sectional view showing one embodiment of a pressure sensitive adhesive sheet provided with protective sheets.

FIG. 2 is a schematic sectional view showing one embodiment of a polarizing plate with a pressure sensitive adhesive layer.

FIG. 3 is a schematic sectional view showing one embodiment of an image display device.

### DESCRIPTION OF EMBODIMENT

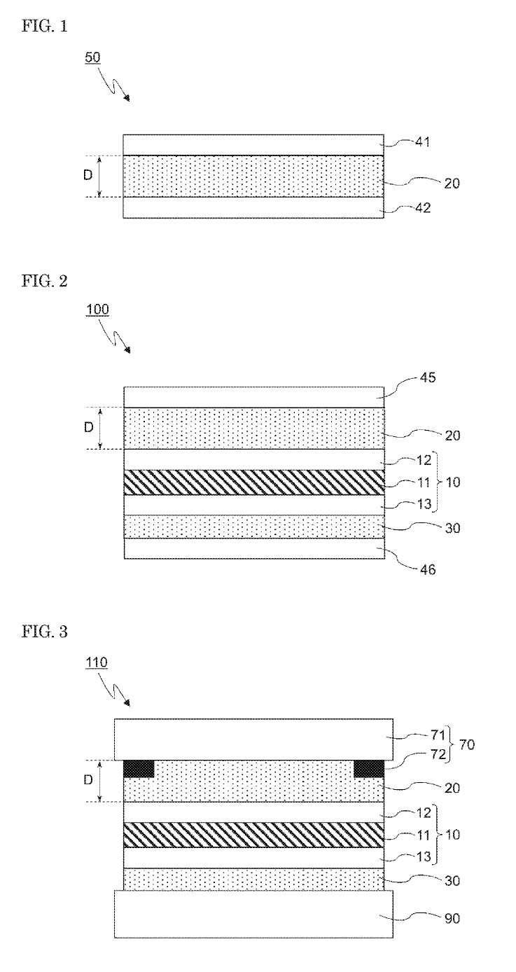

FIG. 1 is a schematic sectional view showing a configuration example of a pressure sensitive adhesive sheet of the present invention. In a pressure sensitive adhesive sheet with a protective sheet 50 shown in FIG. 1, protective sheets 41 and 42 are releasably attached, respectively, on both surfaces of a pressure sensitive adhesive sheet 20. FIG. 2 is a schematic sectional view showing a configuration example of a polarizing plate with a pressure sensitive adhesive layer which includes the pressure sensitive adhesive sheet 20 of the present invention. A polarizing plate with a pressure sensitive adhesive layer 100 shown in FIG. 2 includes the pressure sensitive adhesive sheet 20 (first pressure sensitive adhesive sheet) and another pressure sensitive adhesive sheet 30 (second pressure sensitive adhesive sheet), respectively, on one principal surface (first principal surface) and the other principal surface (second principal surface) of a polarizing plate 10. Protective sheets 45 and 46 are releasably attached on pressure sensitive adhesive sheets 20 and 30, respectively.

FIG. 3 is a schematic sectional view showing a configuration example of an image display device obtained using the pressure sensitive adhesive sheet of the present invention. In an image display device 110 shown in FIG. 3, a front transparent member 70 having a printing level difference 72 on the peripheral edge of a transparent plate 71 is bonded to the polarizing plate 10 with the pressure sensitive adhesive sheet 20 of the present invention interposed therebetween, and the polarizing plate 10 is bonded to an image display cell 90 with another pressure sensitive adhesive sheet 30 interposed therebetween.

The pressure sensitive adhesive sheet 20 is so called an “interlayer filler”, and serve to not only firmly bonding the polarizing plate 10 and the front transparent member 70, but also reduce a refractive index difference at the interface to suppress a reduction in visibility due to reflection and scattering of light. The interlayer filler also functions as a cushion layer against an impact and pressing force on the image display cell 90 such as a liquid crystal cell from the outer surface.

[Properties of Pressure Sensitive Adhesive Sheet]

The pressure sensitive adhesive sheet 20 of the present invention is a sheet shaped pressure sensitive adhesive. The thickness D of the pressure sensitive adhesive sheet 20 is preferably 50 μm or more, more preferably 80 μm or more, further preferably 100 μm or more. By increasing the thickness of the pressure sensitive adhesive sheet to be used as an interlayer filler, level difference absorbency can be imparted to the pressure sensitive adhesive sheet thereby suppressing ingress of bubbles in the vicinity of the printing level difference and display unevenness due to stress strain, even when the front transparent member 70 has the printing level difference 72. When the thickness of the pressure sensitive adhesive sheet is large, moisture is easily dissipated from the side surface of the pressure sensitive adhesive sheet, so that deterioration of display characteristics in exposure of the image display device to a high-temperature environment can be suppressed as described later. Although the upper limit is not particularly limited, the thickness of the pressure sensitive adhesive sheet is preferably 500 μm or less, more preferably 400 μm or less, further preferably 300 μm or less from the viewpoint of productivity etc.

(Optical Characteristics)

Preferably, the pressure sensitive adhesive sheet of the present invention has high transparency. The haze of the pressure sensitive adhesive sheet is preferably 1% or less, and the total light transmittance of the pressure sensitive adhesive sheet is preferably 90% or more. The haze and the total light transmittance are measured in accordance with JIS K7136 using a haze meter.

(Water-Vapor Permeability)

In the pressure sensitive adhesive sheet 20 of the present invention, the product XD² (g/24 h) of the water-vapor permeability X and the square of the thickness D is preferably 2.7×10⁻⁶ or more, more preferably 3.2×10⁻⁶ or more, further preferably 3.9×10⁻⁶ or more. In exposure of an image display device to a high-temperature environment, a decrease in single transmittance at the in-plane central part of the polarizing plate tends to be significantly suppressed as the value XD² increases. The water-vapor permeability is a weight of water vapor permeating through a sample with an area of 1 m² in 24 hours at a relative humidity of 90% at 40° C., and is measured in accordance with the water-vapor permeability test (cup method) in JIS Z0208.

In exposure of an image display device with an interlayer filling configuration to a high-temperature environment, generation of polyene structure in polyvinyl alcohol of a polarizer may be a main factor of decrease in single transmittance of the polarizing plate. In a high-temperature environment, acid components remaining in the pressure sensitive adhesive and the transparent protective film are liberated by moisture to easily move into the polarizer. When heating is performed in the presence of moisture for a long time, (meth)acrylic acid ester components in a polymer that forms the pressure sensitive adhesive, and residual monomers, and cellulose esters in the transparent protective film are hydrolyzed, so that free acid generation is facilitated. In the polyvinyl alcohol-based polarizer, the dehydration reaction of polyvinyl alcohol is catalyzed by free acids, so that a polyene structure (—(C═C)ₙ—) is easily formed. When the polyene structure is formed in the polyvinyl alcohol, the transmittance decreases.

On the other hand, in the present invention, a decrease in single transmittance of the polarizing plate due to polyene structure generation in polyvinyl alcohol can be suppressed by using the pressure sensitive adhesive sheet 20 in which the product XD² of the water-vapor permeability X and the square of the thickness D is large. The reason why generation of polyene structure in polyvinyl alcohol can be suppressed when the value XD² is large may be that moisture easily diffuses to the outside from the end surface of the pressure sensitive adhesive sheet 20, leading to suppression of retention of moisture in the pressure sensitive adhesive sheet.

In general, a water-vapor permeability is used as an index of the amount of moisture dissipated to the outside through a sheet-shaped material such as a film or a pressure sensitive adhesive sheet. In other words, the water-vapor permeability is the amount of moisture dissipated from the principal surface of a sheet-shaped material. In an image display device in which the front transparent member 70 is bonded to a polarizing plate with the pressure sensitive adhesive sheet 20 interposed therebetween, dissipation of moisture from the principal surface cannot be expected, because movement of moisture to the outside is blocked by the front transparent member 70 even when the transparent protective film 12 provided, on the polarizer 11 and the pressure sensitive adhesive sheet 20 provided thereon have a high water-vapor permeability.

The water-vapor permeability X is inversely proportional to the thickness D, and in sheet-shaped materials formed of the same material, the product XD of the water-vapor permeability and the thickness is almost constant. The value XD is an index indicating ease of movement (movement rate) of moisture in the material, and the movement rate of moisture in the pressure sensitive adhesive sheet 20 becomes higher as the value XD of the pressure sensitive adhesive sheet increases. The thickness D of the pressure sensitive adhesive sheet 20 is proportional to the area of the sheet end surface, and as the thickness D increases, moisture arriving at the end surface of the pressure sensitive adhesive sheet is more easily dissipated from the end surface to the outside of the system.

In short, the value XD² is a product of the value XD that is related to ease of movement of moisture in the pressure sensitive adhesive sheet and the value D that is related to ease of dissipation of moisture from the end surface to the outside. Accordingly, as the value XD² increases, moisture at the in-plane central part is more easily dissipated from the end surface of the pressure sensitive adhesive sheet to the outside so that retention of moisture at the in-plane central part of the pressure sensitive adhesive sheet tends to be suppressed. When retention of moisture in the pressure sensitive adhesive sheet is suppressed, generation of free acids due to, for example, hydrolysis of a (meth)acrylic acid ester component in a pressure sensitive adhesive, and a polymer that forms the transparent protective film 12 provided adjacently to the pressure sensitive adhesive sheet 20 is suppressed. Thus, it is considered that the amount of free acids moving into the polarizer decreases, so that acid catalyzed generation of polyene structure in polyvinyl alcohol can be suppressed.

The value XD² of the pressure sensitive adhesive sheet is preferably as large as possible for suppressing a decrease in transmittance due to polyene generation in the polarizer. For ensuring that the value XD² is in the above-mentioned range while the thickness D is in such a range that the pressure sensitive adhesive sheet can exhibit level difference absorbency and cushioning effect, the water-vapor permeability X of the pressure sensitive adhesive sheet 20 is preferably 50 g/m²·24 h or more, more preferably 70 g/m²·24 h or more, further preferably 80 g/m²·24 h or more. The product XD of the water-vapor permeability X and the thickness D of the pressure sensitive adhesive sheet 20 is preferably 1×10⁻² g/m·24 h or more, more preferably 1.5×10⁻² g/m·24 h or more, further preferably 2×10⁻² g/m·24 h or more.

On the other hand, when the water-vapor permeability X is excessively high, movement of moisture from the end surface of the pressure sensitive adhesive sheet into the pressure sensitive adhesive sheet and the polarizing plate may be promoted in a high-temperature and high-humidity environment, leading to deterioration of durability. When the thickness D of the pressure sensitive adhesive sheet is excessively large, productivity of the pressure sensitive adhesive sheet is deteriorated. Accordingly, the value XD² (g/24 h) of the pressure sensitive adhesive sheet is preferably 3×10⁻⁵ or less, more preferably 2.5×10⁻⁵ or less, further preferably 2×10⁻⁵ or less.

(Moisture Content)

In the pressure sensitive adhesive sheet 20 of the present invention, the value Y/D (m⁻¹) obtained by dividing the moisture content Y by the thickness D is preferably 47 or less, more preferably 44 or less, further preferably 40 or less. As the value Y/D decreases, an increase in cross transmittance at the in-plane central part of the polarizing plate in exposure of the image display device to a high-temperature environment tends to be significantly suppressed. The moisture content Y is the amount of moisture per unit mass of the pressure sensitive adhesive, and is measured by a Carl Fischer method using a sample subjected to state adjustment by leaving it standing for 3 days under an atmosphere at a temperature of 23° C. and a humidity of 55%.

As a result of studies conducted by the inventors, it has been found that a decrease in cross transmittance of the polarizing plate after the image display device having an interlayer filling configuration is subjected to a high-temperature durability test is ascribable to an increase in blue light (short-wavelength light) transmittance. Decomposition of polyvinyl alcohol-iodine ion (I₃- and I₅-) complex tends to cause a phenomenon in which the blue light transmittance of a polarizing plate disposed in a cross Nicol state increases (sometimes referred to as “blue light leakage”). Accordingly the main factor of the blue light leakage in the polarizing plate after the high-temperature durability test is decomposition of an iodine complex in the polarizer by moisture and heat.

When the polarizing plate without being bonded to other member is placed under a high-temperature environment, moisture in the polarizer is dissipated from the both principal surfaces and side surfaces (end surfaces) of the polarizing plate. On the other hand, in an image display device in which a gap between a polarizing plate and a front transparent member is filled with a pressure sensitive adhesive sheet, the image display cell 90 and the front transparent member 70 are disposed on the upper and lower principal surfaces of the polarizing plate 10, and therefore moisture existing in the vicinity of the in-plane end part (peripheral edge) is dissipated from the end surface to the outside, whereas moisture existing at the in-plane central part of the polarizing plate is hard to be dissipated to the outside.

In the present invention, an increase in cross transmittance of the polarizing plate due to decomposition of an iodine complex can be suppressed by using the pressure sensitive adhesive sheet 20 having a small Y/D value, which is obtained by dividing the moisture content Y by the thickness D. The reason why a small Y/D value can suppress decomposition of an iodine complex may be that moisture in the polarizing plate easily moves to the pressure sensitive adhesive sheet, leading to suppression of retention of moisture in the polarizer.

The pressure sensitive adhesive has lower moisture content compared with the polarizer and the transparent protective film that form the polarizing plate. Accordingly, as the moisture content Y of the pressure sensitive adhesive sheet 20 provided in contact with the polarizing plate 10 decreases, the moisture concentration difference at the interface between the polarizing plate 10 and the pressure sensitive adhesive sheet 20 increases, so that moisture in the polarizer 11 easily moves to the pressure sensitive adhesive sheet through the transparent protective film 12. The moisture content Y of the pressure sensitive adhesive sheet is an index indicating ease of movement of moisture from the polarizing plate to the pressure sensitive adhesive sheet, and as the moisture content Y decreases, movement of moisture from the polarizing plate to the pressure sensitive adhesive sheet tends to be promoted.

When moisture moves from the polarizing plate 10 to the pressure sensitive adhesive sheet 20, the moisture content in the vicinity of the polarizing plate interface in the pressure sensitive adhesive sheet increases, and the movement rate of moisture from the polarizing plate to the pressure sensitive adhesive sheet decreases. On the other hand, in the pressure sensitive adhesive sheet, moisture moves (diffuses) in the thickness direction of the pressure sensitive adhesive sheet so as to reduce the gradient between the concentration in the vicinity of the interface with the polarizing plate and other portion, and therefore as the thickness D of the pressure sensitive adhesive sheet increases, moisture moving from the polarizing plate 10 to the pressure sensitive adhesive sheet 20 more easily diffuses in the thickness direction of the pressure sensitive adhesive sheet. Accordingly, even when moisture moves from the polarizing plate into the pressure sensitive adhesive sheet, the difference in concentration of moisture at the interface between the polarizing plate 10 and the pressure sensitive adhesive sheet 20 tends to be maintained when the thickness D of the pressure sensitive adhesive sheet increases.

In short, the value Y is related to ease of movement of moisture from the polarizing plate into the pressure sensitive adhesive sheet decreases, and the value D is related to the acceptable diffusion amount of moisture in the pressure sensitive adhesive sheet. Accordingly, as the value Y decreases and as the value D increases, moisture at the in-plane central part of the polarizing plate more easily moves into the pressure sensitive adhesive sheet from the interface between the polarizing plate and the pressure sensitive adhesive sheet. It is considered that as the value Y/D decreases, moisture in the polarizing plate more easily moves to the pressure sensitive adhesive sheet side, so that retention of moisture in the polarizer is suppressed, and thus decomposition of the iodine complex by moisture can be suppressed.

The value Y/D of the pressure sensitive adhesive sheet is preferably as small as possible for suppressing blue light leakage in the polarizing plate. For ensuring that the value Y/D is in the above-mentioned range while the thickness D is in such a range that the pressure sensitive adhesive sheet can exhibit level difference absorbency and cushioning effect, the moisture content Y of the pressure sensitive adhesive sheet 20 is preferably 15 mg/g or less, more preferably 12 mg/g or less, further preferably 9 mg/g or less.

On the other hand, a pressure sensitive adhesive sheet having an excessively low moisture content Y may be poor in adhesiveness with the polarizing plate and the front transparent member. When the pressure sensitive adhesive sheet has excessively low moisture content Y, the water-vapor permeability X tends to decrease, and therefore the single transmittance may decrease although blue light leakage is suppressed. Accordingly, the value Y/D (m⁻¹) of the pressure sensitive adhesive sheet is preferably 1 or more, more preferably 3 or more, further preferably 5 or more.

[Composition of Pressure Sensitive Adhesive]

The pressure sensitive adhesive sheet 20 is formed of pressure sensitive adhesive. The pressure sensitive adhesive includes a base polymer such as an acryl-based polymer, a silicone-based polymer, polyester, polyurethane, polyamide, polyvinyl ether, a vinyl acetate/vinyl chloride copolymer, a modified polyolefin, an epoxy-based polymer, a fluorine-based polymer, a rubber-based polymer such as natural rubber or synthetic rubber, or the like. An acryl-based pressure sensitive adhesive containing an acryl-based polymer can be preferably used as a base polymer because it is excellent in optical transparency exhibits moderate wettability and adhesion characteristics such as cohesiveness and adhesiveness, and is also excellent in weather resistance, heat resistance and the like.

The content of the acryl-based base polymer in the pressure sensitive adhesive sheet of the present invention is preferably 50% by weight or more, more preferably 60% by weight or more. The acryl-based base polymer has (meth)acrylic acid alkyl ester monomer units as a main skeleton. In this specification, the “(meth)acryl” means acryl and/or methacryl. When the base polymer is a copolymer, the arrangement of constituent monomer units may be random or blockwise.

As the (meth)acrylic acid alkyl ester, a (meth)acrylic acid alkyl ester with the alkyl group having 1 to 20 carbon atoms is preferably used. Examples of the (meth)acrylic acid alkyl ester include methyl (meth)acrylate, ethyl (meth)acrylate, butyl (meth)acrylate, isobutyl (meth)acrylate, s-butyl (meth)acrylate, t-butyl (meth)acrylate, pentyl (meth)acrylate, isopentyl (meth)acrylate, neopentyl (meth)acrylate, hexyl (meth)acrylate, heptyl (meth)acrylate, 2-ethylhexyl (meth)acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, isotridodecyl (meth)acrylate, tetradecyl (meth)acrylate, isotetradecyl (meth)acrylate, pentadecyl (meth)acrylate, cetyl (meth)acrylate, heptadecyl (meth)acrylate, octadecyl (meth)acrylate, isooctadecyl (meth)acrylate, nonadecyl (meth)acrylate and aralkyl (meth)acrylate.

The content of the (meth)acrylic acid alkyl ester is preferably 40% by weight or more, more preferably 50% by weight or more, further preferably 60% by weight or more based on the total amount of monomer components that form the base polymer.

Preferably the acryl-based base polymer contains a polar monomer unit in addition to the above mentioned (meth)acrylic acid alkyl ester. Example of the polar monomer unit includes nitrogen-containing monomers and hydroxy group-containing monomers. When the base polymer contains polar monomer unit, high transparency may be kept even when the pressure sensitive adhesive sheet is exposed to a high-temperature and high-humidity environment. In addition, when the base polymer containing a polar monomer unit, the water-vapor permeability of the pressure sensitive adhesive tends to decrease, so that decrease in transmittance of an image display device due to polyene generation in the polarizer under a high-temperature environment can be suppressed.

Examples of the nitrogen-containing monomer include N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, (meth)acryloylmorpholine, N-vinylcarboxylic acid amides and N-vinylcaprolactam. Among them, N-vinylpyrrolidone and (meth)acryloylmorpholine are preferably used.

As the hydroxy group-containing monomer, a hydroxy group-containing (meth)acrylic acid ester such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)-methyl (meth)acrylate or the like is preferably used. As described later, it is preferable that the pressure sensitive adhesive sheet of the present invention is free from acid monomer component. Therefore, the above mentioned “hydroxy group-containing monomer” means an alcoholic hydroxy group-containing monomer, and carboxy-group containing monomers such as (meth)acrylic acid are not included.

Polar group-containing monomers may be used alone, or in combination of two or more thereof. In the pressure sensitive adhesive sheet of the present invention, it is preferable that the base polymer that forms the pressure sensitive adhesive preferably includes both nitrogen-containing monomer component and hydroxy group-containing monomer component. When the base polymer contains both nitrogen-containing monomer component and hydroxy group-containing monomer component, high transparency may be kept as well as the pressure sensitive adhesive has moderate adhesiveness and flexibility.

The ratio of polar monomer units in the base polymer is not particularly limited. The water-vapor permeability and moisture content tend to become higher as the content of polar monomer units increases. For suppressing a decrease in single transmittance and suppressing an increase in cross transmittance of the polarizing plate by ensuring that the moisture content and the water-vapor permeability of the pressure sensitive adhesive sheet are each in the above-mentioned range, the total content of the hydroxy group-containing monomer and the nitrogen-containing monomer based on the total amount of constituent monomer components of the base polymer is preferably 10 to 45% by weight, more preferably 12 to 40% by weight, further preferably 15 to 38% by weight.

Preferably, the pressure sensitive adhesive sheet of the present invention has a low content of organic acid monomers (free organic acids) such as (meth)acrylic acid. When the content of organic acid monomers in the pressure sensitive adhesive sheet is low, a decrease in single transmittance of the polarizing plate due to generation of polyene structure in polyvinyl alcohol is suppressed. The content of (meth)acrylic acid monomers in the acryl-based pressure sensitive adhesive sheet is preferably 100 ppm or less, more preferably 70 ppm or less, further preferably 50 ppm or less. The content of organic acid monomers in the pressure sensitive adhesive sheet is determined in the following manner: the pressure sensitive adhesive sheet is immersed in pure water, and heated at 100° C. for 45 minutes to extract acid monomers in the water, and the acid monomers are quantitatively determined by ion chromatography.

In a thermosetting polymer or a photocurable polymer, existence of unreacted residual monomers is unavoidable. Therefore, it is preferable that the amount of organic acid monomer components such as (meth)acrylic acid in monomer components that form the base polymer is decreased for reducing the content of acid monomers in the pressure sensitive adhesive sheet. Preferably the base polymer is substantially free from an organic acid monomer (carboxy group-containing monomer) as a monomer unit. The content of carboxy group-containing monomer components based on the total amount of constituent monomer components of the base polymer is preferably 0.5% by weight or less, more preferably 0.1% by weight or less, further preferably 0.05% by weight or less.

The acryl-based polymer can be prepared by polymerizing the above-mentioned monomer components by a common polymerization method. Examples of the method for polymerization of an acryl-based polymer include solution polymerization methods, emulsion polymerization methods, mass polymerization methods, and polymerization by irradiation of an active energy ray (active energy ray polymerization methods). Solution polymerization methods or active energy ray polymerization methods are preferable from the viewpoint of transparency, water resistance, costs and so on.

In preparation of the base polymer, a polymerization initiator such as a photopolymerization initiator (photo-initiator) or a thermopolymerization initiator may be used depending on a type of polymerization reaction. Polymerization initiators may be used alone, or in combination of two or more thereof. The molecular weight of the base polymer is appropriately adjusted. The polystyrene-equivalent weight average molecular weight of the base polymer is preferably 50000 to 2000000, more preferably 100000 to 1500000 so that the pressure sensitive adhesive sheet may have moderate viscoelasticity and adhesiveness.

The base polymer may have a crosslinked structure as necessary. The crosslinked structure is formed by for example, adding a crosslinker after polymerization of the base polymer. As the crosslinker, a common cross linker can be used, such as an isocyanate-based crosslinker, an epoxy-based crosslinker, an oxazoline-based crosslinker, an aziridine-based crosslinker, a carbodiimide-based crosslinker or a metal chelate-based crosslinker. T The content of the crosslinker is normally 10 parts by weight or less, preferably 5 parts by weight or less, further preferably 3 parts by weight or less based on 100 parts by weight of the base polymer. When the content of the crosslinker is excessively high, the flexibility (fluidity) of the pressure sensitive adhesive is reduced, so that adhesion to an adherend may be reduced, and ingress of bubbles and display unevenness resulting from the printing level difference of the front transparent member may occur.

When the pressure sensitive adhesive composition includes a crosslinker, it is preferred to perform a heating for crosslinking to form crosslinked structure before bonding to an adherend. The heating temperature and the heating time in the crosslinking treatment are appropriately set according to a type of crosslinker to be used, and crosslinking is normally performed by healing at 20° C. to 160° C. for 1 minute to about 7 days.

Besides the aforementioned acryl-based base polymer, the pressure sensitive adhesive composition may contain a silicone-based polymer, a polyester, a polyurethane, a polyamide, a polyvinyl ether, a vinyl acetate/vinyl chloride copolymer, a modified polyolefin, an epoxy-based polymer, a fluorine-based polymer, or a polymer based on a rubber such as a natural rubber or a synthetic rubber, or the like.

For the purpose of adjusting the adhesive strength, a silane coupling agent can also be added in the pressure sensitive adhesive composition. The silane coupling agent may be used by one kind singly or two or more kinds in combination. When the pressure sensitive adhesive composition includes a silane coupling agent, the content thereof is normally about 0.01 to 5.0 parts by weight, preferably 0.03 to 2.0 parts by weight based on 100 parts by weight of the base polymer.

The pressure sensitive adhesive composition may contain a tackifier as necessary. As the tackifier, for example, a terpene-based tackifier, a styrene-based tackifier, a phenol-based tackifier, a rosin-based tackifier, an epoxy-based tackifier, a dicyclopentadiene-based tackifier, a polyamide-based tackifier, a ketone-based tackifier, an elastomer-based tackifier or the like can be used.

In addition to the components exemplified above, additives such as a plasticizer, a softener, a degradation inhibitor, a filler, a colorant, an ultraviolet ray absorber, an antioxidant, a surfactant and an antistatic agent can be used in the pressure sensitive adhesive composition within the bounds of not impairing the feature of the present invention.

The pressure sensitive adhesive that forms the pressure sensitive adhesive sheet may be formed of a photocurable or thermosetting pressure sensitive adhesive. When the pressure sensitive adhesive is photocurable or thermosetting, it has high fluidity and excellent flexibility at the time of bonding to the front transparent member (before curing), so that ingress of bubbles in the vicinity of the printing level difference of the front transparent member can be suppressed. By curing the pressure sensitive adhesive after the bonding, adhesion reliability is improved. A photocurable pressure sensitive adhesive is especially suitably used from the viewpoint of controlling timing of curing, reliability and so on.

The photocurable pressure sensitive adhesive contains a photocurable component in addition to the base polymer. As the photocurable component, a radical-polymerizable compound (ethylenically unsaturated compound) having a carbon-carbon double bond (C═C bond) is preferably used. The radical-polymerizable compound may be present as a monomer or an oligomer in the pressure sensitive adhesive composition, or may be bonded to a functional group such as a hydroxy group of the base polymer. As the curable pressure sensitive adhesive, one containing a polymerization initiator (photopolymerization initiator or thermopolymerization initiator) is preferable.

When a radical-polymerizable compound is present as a monomer or an oligomer in the pressure sensitive adhesive composition, a polyfunctional polymerizable compound having two or more polymerizable functional groups per molecule is preferably used. Examples of the polyfunctional polymerizable compound include compounds having two or more C═C bonds per molecule, and compounds having one C═C bond, and a polymerizable functional group such as epoxy, aziridine, oxazoline, hydrazine or methylol. Among them, polyfunctional polymerizable compounds having two or more C═C bonds, like polyfunctional acrylates, are preferable.

The method of photocuring is preferably a method in which a system containing a photocurable compound oligomer and a photopolymerization initiator is irradiated with an active ray such as an ultraviolet ray. A system using an ethylenically unsaturated compound and a photoradical generator is preferred because it has a high level of photosensitivity and can be selected from a wide range of materials. The content of the photocurable compound in the photocurable pressure sensitive adhesive is preferably 2 to 50 parts by weight, more preferably 5 to 30 parts by weight based on 100 parts by weight of the whole pressure sensitive adhesive composition. When the content of the photocurable compound falls within the above-mentioned range, reliability of the adhesion after the curing can be improved, while the flexibility of the pressure sensitive adhesive before curing is remained.

[Preparation of Pressure Sensitive Adhesive Sheet]

The pressure sensitive adhesive sheet can be obtained by applying the pressure sensitive adhesive composition solution onto an appropriate base and then drying a solvent etc. Various kinds of coating methods are applicable for formation of the pressure sensitive adhesive sheet. Specific examples include roll coating, kiss roll coating, gravure coating, reverse coating, roll brushing, spray coating, dip roll coating, bar coating, knife coating, air knife coating, curtain coating, lip coating, and extrusion coating methods using a die coater etc. Among them, use of a die coater is preferred, and in particular, use of a die coater using a fountain die or a slot die is more preferred.

As a method for drying the applied pressure sensitive adhesive composition, a suitable method can be appropriately employed according to a purpose. The heating/drying temperature is preferably 40° C. to 200° C. Suitable drying time can be appropriately employed. The drying time is preferably 5 seconds to 20 minutes.

Protective sheets 41 and 42 are releasably attached on the pressure sensitive adhesive sheet 20, as necessary. The protective sheets 41 and 42 are provided for protecting the exposed surfaces of the pressure sensitive adhesive sheet 20, until the pressure sensitive adhesive sheet 20 is bonded to the polarizing plate 10 and the front transparent member 70. As the protective sheets, a plastic film made of polyethylene, polypropylene, polyethylene terephthalate, polyester, or the like is preferably used. A substrate used for formation of the pressure sensitive adhesive sheet (application of the pressure sensitive adhesive composition) may be used as it is as a protective sheet. Releasability of the protective sheet from the pressure sensitive adhesive sheet in practical use can be improved by appropriately subjecting the surface thereof to a release treatment with using silicone, long-chain alkyl, fluorine or the like.

[Image Display Device]

The pressure sensitive adhesive sheet of the present invention is suitably used for bonding the polarizing plate to the front transparent member in the image display device. The image display device 110 shown in FIG. 3 includes the polarizing plate 10 on the viewing-side of the image display cell 90 such as a liquid crystal cell or an organic EL cell, and further includes the front transparent member 70 on the viewing-side of the polarizing plate 10. An optical film such as a polarizing plate or an optical element such as a backlight (not illustrated) may be provided on a side opposite to the viewing-side of the image display cell 90. The front transparent member 70 is bonded to the polarizing plate 10 with the pressure sensitive adhesive sheet 20 of the present invention interposed therebetween.

(Polarizing Plate)

The polarizing plate 10 includes the polarizer 11. The polarizer 11 is a polyvinyl alcohol-based film containing iodine. As a material of the polyvinyl alcohol-based film to be used as the polarizer, polyvinyl alcohol or a derivative thereof is used. Examples of the derivative of polyvinyl alcohol include polyvinyl formal and polyvinyl acetal as well as polyvinyl alcohol modified with an olefin such as ethylene or propylene, an unsaturated carboxylic acid such as acrylic acid, methacrylic acid or crotonic acid, or an alkyl ester thereof, and an acryl amide. As the polyvinyl alcohol, one having a polymerization degree of about 1000 to 10000 and a saponification degree of about 80 to 100% by mol is generally used.

The polarizer can be obtained by iodine-dying and stretching the polyvinyl alcohol-based film. A thin polarizer having a thickness of 10 μm or less may also be used. Examples of the thin polarizer include thin, polarizers as described in JP 51-069644 A, JP 2000-338329 A, WO 2010/100917, JP 4691205 B, JP 4751481 B, and so on. These thin polarizers are obtained by, for example, a production method including the steps of stretching a laminate of polyvinyl alcohol-based resin layer and a stretchable resin base material; and performing iodine dying to the polyvinyl alcohol-based resin layer.

Preferably, the polarizing plate 10 includes transparent protective films 12 and 13 adjacent to the polarizer 11. Preferably, the polarizer 11 is bonded to the transparent protective films 12 and 13 with an appropriate adhesive (not illustrated) interposed therebetween. The material that forms the transparent protective film is, for example, a thermoplastic resin excellent in transparency, mechanical strength and heat stability. Specific examples of the thermoplastic resin include cellulose-based resins such as triacetyl cellulose, polyester-based resins, polyether sulfone-based resins, polysulfone-based resins, polycarbonate-based resins, polyamide-based resins, polyimide-based resins, polyolefin-based resins, (meth)acryl-based resin, cyclic polyolefin-based resins (norbornene-based resins), polyarylate-based resins, polystyrene-based resins, polyvinyl alcohol-based resins, and mixtures thereof.

The water-vapor permeability of the transparent protective film 12 disposed on the polarizer 11 on the front transparent member 70 side (viewing-side) is preferably 300 g/m²·24 h or more, more preferably 500 g/m²·24 h or more, further preferably 700 g/m²·24 h or more. When the water-vapor permeability of the transparent protective film 12 is high, retention of moisture in the polarizer can be suppressed. By performing drying by heating etc. before the process for production of the polarizing plate or before bonding the polarizing plate to the pressure sensitive adhesive sheet, moisture in the polarizer can be dissipated to the outside of the polarizing plate to reduce the amount of moisture in the polarizer. When the water-vapor permeability of the transparent protective film is high, generation of polyene structure, decomposition of iodine complex, and the like tend to be suppressed, because moisture is easily dissipated to the outside of the polarizing plate.

A cellulose-based resin is suitably used as a material of the transparent protective film 12 for ensuring that the water-vapor permeability is in the above-mentioned range. The cellulose-based resin is, for example, an ester of cellulose and a fatty acid. Specific examples of the cellulose ester include cellulose acetates such as triacetyl cellulose and diacetyl cellulose, cellulose propionate and cellulose butyrate.

(Front Transparent Member)

The front transparent member 70 is, for example, a front transparent plate (window layer) or a touch panel. As the front transparent plate, a transparent plate having appropriate mechanical strength and thickness. As this transparent plate, for example, a transparent resin plate such as that of an acryl-based resin or a polycarbonate-based resin, or a glass plate is used. As the touch panel, a touch panel of any type such as resistive film type, capacitance type, optical type or ultrasonic type is used.

(Cell-Side Pressure Sensitive Adhesive)

Cell-side pressure sensitive adhesive sheet 30 which is used for bonding the polarizing plate 10 and the image display cell 90 is not particularly limited. As the pressure sensitive adhesive for the cell-side pressure sensitive adhesive sheet 30, one containing as a base polymer an acryl-based polymer, a silicone-based polymer, a polyester, a polyurethane, a polyamide, a polyvinyl ether, a vinyl acetate/vinyl chloride copolymer, a modified polyolefin, an epoxy-based polymer, a fluorine-based polymer, or a polymer based on a rubber such as a natural rubber or a synthetic rubber can be appropriately selected and used. Particularly, an acryl-based pressure sensitive adhesive is preferably used because it is excellent in optical transparency, exhibits moderate pressure sensitive adhesion properties such as wettability, cohesive strength and adhesiveness, and is also excellent in weather resistance, heat resistance and the like.

Although the thickness of the cell-side pressure sensitive adhesive sheet 30 is not particularly limited, it is preferably 3 μm to 35 μm, more preferably 5 μm to 32 μm, and further preferably 10 μm to 30 μm, in view of adhesion properties and handling characteristics.

(Bonding of Optical Members)

The order in which optical members are bonded in formation of the image display device is not particularly limited. For example, the image display cell 90 is bonded to the polarizing plate 10 with the cell-side pressure sensitive adhesive sheet 30 interposed therebetween to form an image display panel, and the polarizing plate 10 on a surface of the image display panel is bonded to the front transparent member 70 with the viewing-side pressure sensitive adhesive sheet 20 (pressure sensitive adhesive sheet of the present invention) interposed therebetween. The front transparent member 70 may be bonded to the polarizing plate 10 before the image display cell 90 is bonded to the polarizing plate 10. The front transparent member 70 and the image display cell 90 can be simultaneously bonded to the polarizing plate 10.

For improving workability in bonding and the arranging angle precision (axis precision) of the polarizing plate, it is preferred that the polarizing plate 10 is bonded to the front transparent member 70 with the viewing-side pressure sensitive adhesive sheet 20 interposed therebetween after the polarizing plate 10 is bonded to the image display cell 90 with the cell-side pressure sensitive adhesive sheet 30 interposed therebetween

At the time when the front transparent member 70 is bonded to the polarizing plate 10 with the pressure sensitive adhesive sheet 20 interposed therebetween, bubbles are easily generated on the periphery thereof due to the printing level difference 72 provided on the peripheral edge. Accordingly, when the polarizing plate 10 is bonded to the front transparent member 70 using the pressure sensitive adhesive sheet 20 of the present invention, it is preferable to perform the bonding under vacuum.

Preferably, degassing is performed for removing bubbles at the interface between the pressure sensitive adhesive sheet 20 and the front transparent member 70 and in the vicinity of non-flat portions such as the printing level difference 72 after the polarizing plate 10 is bonded to the front transparent member 70. As a degassing method, an appropriate method such as heating, pressurization or pressure reduction can be employed. For example, it is preferred that bonding is performed while ingress of bubbles is suppressed under reduced pressure and heating, and pressurization is then performed in parallel with heating through autoclave or the like for the purpose of, for example, suppressing delay bubbles. When degassing is performed by heating, the heating temperature is in a range of generally about 30° C. to 100° C., preferably 40° C. to 90° C., more preferably 50° C. to 80° C. When pressurization is performed, the pressure is in a range of generally about 0.05 MPa to 2 MPa, preferably 0.1 MPa to 1.5 MPa, more preferably 0.2 MPa to 1 MPa.

[Polarizing Plate with Pressure Sensitive Adhesive Layer]

When an image display device is formed using the pressure sensitive adhesive sheet of the present invention, a polarizing plate with a pressure sensitive adhesive layer in which a pressure sensitive adhesive sheet and a polarizing plate are laminated may be provided, followed by bonding pressure sensitive adhesive sheet of the polarizing plate with a pressure sensitive adhesive layer to a front transparent member. FIG. 2 is a sectional view schematically showing one example of a polarizing plate with a pressure sensitive adhesive layer on both sides which includes a viewing-side pressure sensitive adhesive sheet 20 (first pressure sensitive sheet) on one surface (first principal surface) of a polarizing plate 10, and includes a cell-side pressure sensitive adhesive sheet 30 (second pressure sensitive sheet) on the other surface (second principal surface) of the polarizing plate 10. Protective sheets 45 and 46 are releasably attached on the surfaces of pressure sensitive adhesive sheets 20 and 30, respectively. In the polarizing plate with a pressure sensitive adhesive layer on both sides 100, the viewing-side pressure sensitive adhesive sheet 20 is used for bonding the polarizing plate to the front transparent plate on the viewing-side, and the cell-side pressure sensitive adhesive sheet 30 is used for bonding the polarizing plate to a liquid crystal cell etc.

When a polarizing plate with a pressure sensitive adhesive in which the pressure sensitive adhesive sheet 20 is provided, on the polarizing plate 10 is used, it is not necessary to carry out a process of providing another pressure sensitive sheet on the polarizing plate for interlayer filling in production of the image display device. Therefore, the production process of the image display device can be simplified, and contamination due to protrusion of a pressure sensitive adhesive is prevented.

(Provision of Pressure Sensitive Adhesive Sheet on Polarizing Plate)

Examples of the method for providing pressure sensitive adhesive sheets 20 and 30 on the polarizing plate 10 include a method in which a pressure sensitive adhesive composition is applied to a release-treated base material etc., and dried or cured as necessary to form a pressure sensitive adhesive sheet, and the pressure sensitive adhesive sheet is then transferred onto the polarizing plate 10; and a method in which a pressure sensitive adhesive composition is applied to the polarizing plate 10, and dried or cured on the polarizing plate as necessary to form a pressure sensitive adhesive layer on the polarizing plate.

Protective sheets 45 and 46 are releasably attached on the pressure sensitive adhesive sheets 20 and 30, respectively, as necessary. Separators (base materials for applying the pressure sensitive adhesive layer) etc. used in transferring the pressure sensitive adhesive sheets 20 and 30 onto the polarizing plate 10 may be as protective sheets 45 and 46 for the polarizing plate with a pressure sensitive adhesive layer.

### Examples

The present invention will be described more specifically below by showing examples and comparative examples, but the present invention is not limited to these examples.

[Measurement Methods]

(Amount of Moisture in Polarizing Plate)

A polarizing plate was subjected to state adjustment by leaving it standing under an atmosphere at a temperature of 23° C. and a humidity of 55% for 3 days, and then cut to a size of 10 cm square. The initial weight m₀ was measured, and the dry weight m₁ after drying at 120° C. for 2 hours was determined. The amount of moisture per unit area (g/cm²) was calculated from the following equation.

Amount of moisture=(m₁·m₀)/sample area

(Water Vapor Permeability of Transparent Protective Film)

The water-vapor permeability was measured in an atmosphere at a temperature of 40° C. and a humidity of 90% in accordance with the water-vapor permeability test (cup method) in JIS Z0208.

(Moisture Content of Pressure Sensitive Adhesive Sheet)

A pressure sensitive adhesive sheet with a separator on both sides was subjected to state adjustment by leaving it standing under an atmosphere at a temperature of 23° C. and a humidity of 55% for 3 days. The sample after the state adjustment was cut to 10 cm² (two samples each having a size of 1 cm×5 cm), the separators were peeled off from the pressure sensitive adhesive sheet, the pressure sensitive adhesive sheet was bonded to an aluminum foil, the weight thereof was measured, and the moisture content was then measured under the following conditions by a Karl Fischer coulometric titration method using a moisture content meter (Model CA-200 manufactured by Mitsubishi Chemical Analytech Co., Ltd.) including a heating vaporizer (Model VA-200 manufactured by Mitsubishi Chemical Analytech Co., Ltd.).

Anolyte: AQUAMICRON AKX (manufactured by Mitsubishi Chemical Corporation)

Catholyte: AQUAMICRON CXU (manufactured by Mitsubishi Chemical Corporation)

Heating vaporizing temperature: 150° C.

(Water-Vapor Permeability of Pressure Sensitive Adhesive Sheet)

A pressure sensitive adhesive sheet subjected to state adjustment in the same manner as in the measurement of the moisture content was used as a sample. A separator on one surface of the pressure sensitive adhesive sheet was peeled off from the pressure sensitive adhesive sheet, and the pressure sensitive adhesive sheet was bonded to a 25 μm-thick triacetyl cellulose film (water-vapor permeability: 1070 g/m²·24 h), a separator on the other surface was then peeled off, and the water-vapor permeability was measured in an atmosphere at a temperature of 40° C. and a humidity of 90% in accordance with the water-vapor permeability test (cup method) in JIS Z0208. Although the water-vapor permeability obtained here was the water-vapor permeability of a laminate of the triacetyl cellulose film and the pressure sensitive adhesive sheet, the water-vapor permeability of the laminate was considered equal to the water-vapor permeability of the pressure sensitive adhesive sheet because the water-vapor permeability of the triacetyl cellulose film was sufficiently higher than the water-vapor permeability of the pressure sensitive adhesive sheet.

[Preparation of Viewing-Side Pressure Sensitive Adhesive Sheet]

<Pressure Sensitive Adhesive Sheets A to G>

(Polymerization of Prepolymer)

Monomer components (total amount: 100 parts by weight) as shown in Table 1 and 0.1 part by weight of 2,2-dimethoxy-1,2-diphenylethane-1-one (trade name: IRGACURE 651 manufactured by BASF Ltd.) as a photopolymerization initiator were introduced into a separable flask provided with a thermometer, a stirrer, a reflux cooling tube and a nitrogen gas inlet, and a nitrogen gas was then fed to perform nitrogen purge for 1 hour while the mixture was stirred. Thereafter, polymerization was performed by irradiation with UVA at 5 mW/cm² under a nitrogen atmosphere to prepare a prepolymer composition. The polymerization time was adjusted so that the polymerization ratio of the prepolymer would be 5 to 15%. In Table 1, each of the components is described by abbreviation indicated below.

2EHA: 2-ethylhexyl acrylate

ISA: isostearyl acrylate

LA: lauryl acrylate

HEA: hydroxyethyl acrylate

NVP: N-vinylpyrrolidone

AA: acrylic acid

(Preparation of Pressure Sensitive Adhesive Composition)

The following compounds were added to the obtained acryl-based prepolymer composition (total amount: 100 parts by weight) to prepare a photopolymerizable pressure sensitive adhesive composition: 0.1 part by weight of 1,6-hexanediol diacrylate (trade name “NK ESTER A-HD-N” manufactured by Shin-Nakamura Chemical Co., Ltd) as a polyfunctional monomer; 0.3 parts by weight of 3-glycidoxypropyltrimethoxysilane (trade name “KBM-403” manufactured by Shin-Etsu Silicones) as a slime coupling agent; and 0.1 part by weight of IRGACURE 651 as a photopolymerization initiator.

(Preparation of Pressure Sensitive Adhesive Sheet)

The pressure sensitive adhesive composition was applied onto a release-treated PET film (light release separator) in such a manner that the thickness would be 200 μm, and another PET film (heavy release separator) was laminated onto the applied layer. Thereafter, the applied layer was irradiated with UVA (integrated light amount: 3000 mJ/cm²) at 5 mW/cm² from above the separator to advance polymerization, so that a pressure sensitive adhesive sheet with a separator on both sides was obtained.

<Pressure Sensitive Adhesive Sheets H and I>

Except that the application thickness in preparation of the pressure sensitive adhesive sheet was changed to each of 100 μm and 500 μm, the same procedure as in the case of the pressure sensitive adhesive sheet B was carried out to obtain a pressure sensitive adhesive sheet.

[Preparation of Cell-Side Pressure Sensitive Adhesive Sheet]

(Polymerization of Base Polymer)

97 parts by weight of butyl acrylate, 3 parts of acrylic acid, 0.2 part by weight of AIBN as a polymerization initiator and 233 parts by weight of ethyl acetate were put into a separable flask provided with a thermometer, a stirrer, a reflux cooling tube and a nitrogen gas inlet, and a nitrogen gas was then fed to perform nitrogen purge for 1 hour while the mixture was stirred. Thereafter, the flask was heated to 60° C., the mixture was reacted for 7 hours to obtain an acryl-based polymer having a weight average molecular weight (Mw) of 1100000.

(Preparation of Pressure Sensitive Adhesive Composition)

The following compounds were added to the obtained acryl-based polymer solution in the following amounts based on 100 parts by weight of the solid component in the polymer solution to prepare a pressure sensitive adhesive composition solution: 0.8 parts by weight of trimethylolpropane-tolylene diisocyanate (“CORONATE L” manufactured by Nippon Polyurethane Industry Co., Ltd.) as an isocyanate-based crosslinker; and 0.1 part by weight of 3-glycidyloxypropyltrimethoxysilane (trade name “KBM-403” manufactured by Shin-Etsu Silicones) as a Silane coupling agent.

The pressure sensitive adhesive composition solution was applied onto a light release separator in such a manner that the thickness after drying would be 23 μm, the applied solution was heated and dried at 100° C. for 3 minutes to remove the solvent, and a heavy release separator was then laminated thereon. Thereafter, the laminate was heated at 50° C. for 48 hours to perform a crosslinking treatment, so that a pressure sensitive adhesive sheet with a separator on both sides was obtained. The pressure sensitive adhesive sheet had a water-vapor permeability of 102 g/m²·24 h and a moisture content of 0.7 mg/g.

[Polarizing Plate]

A polarizing plate (polarization degree: 99.995%, moisture content: 5.1 g/m²) with a transparent protective film laminated on each of both surfaces of a polarizer formed of a 25 μm-thick stretched polyvinyl alcohol film impregnated with iodine was used. The transparent protective film on one surface (cell-side) of the polarizer was a 30 μm-thick acryl-based film (water-vapor permeability: 120 g/m²·24 h), and the transparent protective film on the other surface (viewing-side) was a 40 μm-thick triacetyl cellulose film (water-vapor permeability: 984 g/m²·24 h).

[Preparation of Polarizing Plate with Pressure Sensitive Adhesive Layer on Both Sides]

The cell-side pressure sensitive adhesive sheet was laminated to the cell-side surface of the polarizing plate, and each of the pressure sensitive adhesive sheets A to I was laminated to the viewing-side surface of the polarizing plate to obtain each of polarizing plates A to I with a pressure sensitive adhesive layer on both sides. In lamination of the polarizing plate to the pressure sensitive adhesive sheet, the light release separator was peeled off from the surface of the pressure sensitive adhesive sheet, and the polarizing plate was laminated onto the exposed surface of the pressure sensitive adhesive sheet.

[Preparation of Panel for Evaluation]

Each of the polarizing plates A to I with a pressure sensitive adhesive layer on both sides was cut to a size of 200 mm×140 mm, the separator on the cell-side pressure sensitive adhesive sheet was peeled off, and the exposed surface of the pressure sensitive adhesive sheet was then bonded onto a glass plate (280 mm×180 mm×0.7 mm) using a hand roller. Thereafter, the separator on the viewing-side pressure sensitive adhesive sheet was peeled off, and a glass plate (280 mm×180 mm×0.7 mm) was placed on the exposed surface of the pressure sensitive adhesive sheet, and bonded onto the pressure sensitive adhesive sheet by a vacuum press bonding device (device internal pressure: 30 Pa, bonding surface pressure: 0.3 MPa, bonding time: 5 seconds). Thereafter, an autoclave treatment was performed (temperature: 50° C., pressure: 0.5 MPa, time 15 minutes). In this way, a pseudo panel for evaluation in which a glass plate is bonded to each of both surfaces of a polarizing plate with a pressure sensitive adhesive sheet interposed therebetween was obtained.

(Change in Transmittance in Heating Test)

The single transmittance at the in-plane central part of the pseudo panel was measured. The transmittance is a tristimulus value Y obtained by performing visibility correction with a 2-degree visual field (C light source) in JIS Z8701. The pseudo panel after measurement of the single transmittance was put in a hot air oven at a temperature of 95° C., and subjected to heating test, and the cross transmittance after 300 hours and the single transmittance after 500 hours were measured. The cross transmittance was measured with another polarizing plate (polarization degree: 99.995%) disposed on the pseudo panel.

[Evaluation Results]

The base polymer composition of each pressure sensitive adhesive sheet, the thickness of the pressure sensitive adhesive sheet, and results of evaluation on a change in single transmittance and the cross transmittance of the pseudo panel after the heating test are shown in Table 1. For the single transmittance, samples with a transmittance decrease ratio of less than 2% after the 500-hour heating test were rated. A, samples with a transmittance decrease ratio of 2% or more and less than 5% after the 500-hour heating test were rated B, and samples with a transmittance decrease ratio of 5% or more after the 500-hour heating test were rated C. For the cross transmittance, samples with a value of less than 0.03% after the 300-hour heating test were rated A, samples with a value of 0.03% or more and less than 0.08% after the 300-hour heating test were rated B, and samples with a value of 0.08% or more after the 300-hour heating test were rated C.

TABLE 1

| | viewing-side pressure sensitive adhesive sheet | | | | | | | | | | | | |
|---|---|---|---|---|---|---|---|---|---|---|---|---|---|
| | | | | | | | | water-vapor | moisture | | | panel heating test result | |
| | | | | | | | thickness | permeability | content | XD² × | | single | cross |
| | monomer composition | | | | | | D | X | Y | 10⁻⁶ | Y/D | transmittance | transmittance |
| | 2EHA | ISA | LA | HEA | NVP | AA | [μm] | [g/m² · 24 h] | [mg/g] | [g/24 h] | [m⁻¹] | 500 h | 300 h |
| A | 58 | — | — | 27 | 15 | — | 200 | 220 | 9.6 | 8.8 | 48 | A | B |
| B | 66 | — | — | 19 | 15 | — | 200 | 178 | 8.0 | 7.1 | 40 | A | A |
| C | 60 | — | 22 | 8 | 10 | — | 200 | 158 | 2.7 | 6.3 | 14 | A | A |
| D | 40 | 35 | — | 6 | 19 | — | 200 | 121 | 5.0 | 4.8 | 25 | A | A |
| E | 40 | 40 | — | 1 | 19 | — | 200 | 98 | 3.0 | 3.9 | 15 | A | A |
| F | 40 | 47 | — | 1 | 12 | — | 200 | 65 | 2.6 | 2.6 | 13 | B | A |
| G | 40 | 37 | — | 1 | 17 | 5 | 200 | 112 | 2.5 | 4.5 | 13 | C | A |
| H | 66 | — | — | 19 | 15 | — | 500 | 71 | 8.0 | 17.8 | 16 | A | A |
| I | 66 | — | — | 19 | 15 | — | 100 | 356 | 8.0 | 3.6 | 80 | A | C |

In the results of evaluation of pseudo panels having 200 μm-thick viewing-side pressure sensitive adhesive sheets A to F, the single transmittance after the heating test tends to decrease when the water-vapor permeability X of the pressure sensitive adhesive sheet is low, and the cross transmittance after the heating test tends to increase when the moisture content Y of the pressure sensitive adhesive sheet is high. In the results of evaluation of pseudo panels having pressure sensitive adhesive sheets B, H and I, having the same pressure sensitive adhesive composition and different thicknesses, both a change in single transmittance and a change in cross transmittance after the heating test tend to be suppressed when the thickness D of the pressure sensitive adhesive sheet is large. These results show that a change in single transmittance is related to the water-vapor permeability X and the thickness D of the pressure sensitive adhesive sheet, and a change in cross transmittance is related to the moisture content Y and the thickness D of the pressure sensitive adhesive sheet.

Comprehensive consideration of the evaluation results of panels having pressure sensitive adhesive sheets A to F, H and I suggests the following: as the product XD² of the water-vapor permeability X and the square of the thickness D of the pressure sensitive adhesive sheet increases, a decrease in single transmittance is more significantly suppressed; and as the value Y/D obtained by dividing the moisture content Y by the thickness D of the pressure sensitive adhesive sheet, an increase in cross transmittance is more significantly suppressed.

In the panel having the pressure sensitive adhesive sheet G containing an acrylic acid monomer component as a base polymer of the pressure sensitive adhesive, the single transmittance markedly decreased after the heating test although the value XD² of the pressure sensitive adhesive sheet was equivalent to that of the pressure sensitive adhesive sheet D. This result shows that an increase in single transmittance in the panel obtained using the pressure sensitive adhesive sheet G is caused by an acid, and thus a change in single transmittance can be suppressed by using an acid-free pressure sensitive adhesive.

What is claimed is:

1. A pressure sensitive adhesive sheet, which is to be used for bonding a polarizing plate to a transparent member disposed on a viewing-side of an image display device,
the pressure sensitive adhesive sheet having a thickness of D, a water-vapor permeability of X, and a moisture content of Y, wherein
XD² is 2.7×10⁻⁶ g/24 h or more and Y/D is 47 m⁻¹ or less, and
a base polymer of a pressure sensitive adhesive composition that forms the pressure sensitive adhesive sheet is substantially free from an organic acid monomer component as monomer units.

2. The pressure sensitive adhesive sheet according to claim 1, wherein the thickness D is 50 μm to 500 μm.

3. The pressure sensitive adhesive sheet according to claim 1, wherein the pressure sensitive adhesive composition contains 50% by weight or more of an acryl-based base polymer.

4. The pressure sensitive adhesive sheet according to claim 3, wherein the acryl-based base polymer contains a hydroxy group-containing monomer and a nitrogen-containing monomer as monomer units, and
a total content of the hydroxy group-containing monomer and the nitrogen-containing monomer based on a total amount of constituent monomer components of the acryl-based base polymer is 10 to 45% by weight.

5. A polarizing plate with a pressure sensitive adhesive: comprising a polarizing plate; and a first pressure sensitive adhesive sheet laminated on a first principal surface of the polarizing plate, wherein
the polarizing plate includes a polarizer formed of a polyvinyl alcohol-based film containing iodine,
the pressure sensitive adhesive sheet has a thickness of D, a water-vapor permeability of X, and a moisture content of Y, XD² is 2.7×10⁻⁶ g/24 h or more and Y/D is 47 m⁻¹ or less, and
a base polymer of a pressure sensitive adhesive composition that forms the first pressure sensitive adhesive sheet is substantially free from an organic acid monomer component as monomer units.

6. The polarizing plate with a pressure sensitive adhesive according to claim 5, wherein the thickness D of the pressure sensitive adhesive sheet is 50 μm to 500 μm.

7. The polarizing plate with a pressure sensitive adhesive according to claim 5, wherein the pressure sensitive adhesive composition contains 50% by weight or more of an acryl-based base polymer.

8. The polarizing plate with a pressure sensitive adhesive according to claim 7, wherein the acryl-based base polymer contains a hydroxy group-containing monomer and a nitrogen-containing monomer as monomer units, and
a total content of the hydroxy group-containing monomer and the nitrogen-containing monomer based on a total amount of constituent monomer components of the acryl-based base polymer is 10 to 45% by weight.

9. The polarizing plate with a pressure sensitive adhesive according to claim 5, wherein the polarizing plate further includes a transparent protective film on the polarizer on a side the first pressure sensitive adhesive sheet is laminated.

10. The polarizing plate with a pressure sensitive adhesive according to claim 9, wherein the transparent protective film has a water-vapor permeability of 300 g/m²·24 h or more.

11. The polarizing plate with a pressure sensitive adhesive according to claim 5 further comprising a second another pressure sensitive adhesive sheet having a thickness of 35 μm or less provided on a second principal surface of the polarizing plate.

12. An image display device comprising: an image display panel including an image display cell and a polarizing plate provided on a viewing-side of the image display cell; and a transparent member provided on a viewing-side of the image display panel, wherein
the polarizing plate includes a polarizer formed of a polyvinyl alcohol-based film containing iodine,
the polarizing plate and the transparent member are bonded together with a pressure sensitive adhesive sheet,
the pressure sensitive adhesive sheet has a thickness of D, a water-vapor permeability of X, and a moisture content of Y, XD² is 2.7×10⁻⁶ g/24 h or more and Y/D is 47 m⁻¹ or less, and
a base polymer of a pressure sensitive adhesive composition that forms the pressure sensitive adhesive sheet is substantially free from an organic acid monomer component as monomer units.
